(19) United States
(12) Patent Application Publication
(10) Pub. No.: US 2025/0048677 A1
(43) Pub. Date: Feb. 6, 2025

(54) BACKSIDE POWER RAIL TO BACKSIDE CONTACT CONNECTION

(71) Applicant: International Business Machines Corporation, Armonk, NY (US)

(72) Inventors: Tao Li, Slingerlands, NY (US); Ruilong Xie, Niskayuna, NY (US); Tsung-Sheng Kang, Ballston Lake, NY (US); Nicholas Alexander Polomoff, Hopewell Junction, NY (US); Huimei Zhou, Albany, NY (US)

(21) Appl. No.: 18/363,889

(22) Filed: Aug. 2, 2023

(51) Int. Cl. H01L 29/423; H01L 23/528; H01L 27/092; H01L 29/06; H01L 29/417; H01L 29/66; H01L 29/775; H01L 29/786

(52) U.S. Cl. CPC H01L 29/42392; H01L 23/5286; H01L 27/0924; H01L 27/0928; H01L 29/0673; H01L 29/41733; H01L 29/66439; H01L 29/775; H01L 29/78696

(57) ABSTRACT

A semiconductor device includes first nanosheet structures at an NFET region of a semiconductor substrate and second nanosheet structures at a PFET region. A first gate wraps around the first nanosheet structures and a second gate wraps around the second plurality of nanosheet structures. A dielectric bar is between the first nanosheet structures and the second nanosheet structures. The semiconductor device further includes a first backside contact in the NFET region and a second backside contact in the PFET region. The first backside contact includes a first backside contact extension that extends to a first side of the at least one dielectric bar. The second backside contact includes a second backside contact extension that extends to an opposing second side of the at least one dielectric bar. One or more backside power elements are on one or both of the first backside contact extension and the second contact extension.

### BACKGROUND

The present invention generally relates to fabrication methods and resulting structures for semiconductor devices, and more specifically, to processing methods and resulting structures for providing an improved backside power rail to backside contact connection.

The development of an integrated circuit (i.e., chip) involves several stages from design through fabrication. Many aspects of the development are performed iteratively to ensure that the chip ultimately manufactured meets all design requirements. Defining the chip architecture is one of the earliest phases of integrated circuit development. The power (e.g., power requirement), performance (e.g., timing), and area (i.e., space needed) for the resulting chip, collectively referred to as “PPA”, is one of the primary metrics by which integrated circuits are evaluated. PPA is largely a consequence of the chip architecture.

Semiconductor fabrication continues to evolve towards improving one or more aspects of PPA. For example, a higher number of active devices (mainly transistors) of ever decreasing device dimensions are placed on a given surface of semiconductor material. Density scaling has put a strain on the design and fabrication of the interconnects between the front end of line of the integrated circuit, consisting mainly of the active devices, and the contact terminals of the integrated circuit. In many chip architectures, all of these interconnects are incorporated in the back end of line (BEOL) structure of the integrated circuit, which includes a stack of metallization layers and vertical via connections built on top of the front end of line (FEOL) structure.

Integrated circuits (ICs) may sometimes include a backside power delivery network (BSPDN). The BSPDN is defined by the conductors and vias (sometimes referred to as backside power rails) connected to the power supply (VDD) and ground (VSS) terminals of the chip. The BSPDN is responsible for delivering power to the individual devices in the back side. The integration of the BSPDN to the backside of the devices has become particularly challenging as device densities continue to scale. Backside power delivery is one known solution to this problem, and involves moving some (or most, or all) layers of the BSPDN from the front side of the integrated circuit to the back side. In a backside-style architecture, the repositioned layers are not formed on top of the FEOL, but are instead formed on the opposite side of the chip (i.e., on the backside of the semiconductor substrate onto which the active devices have been built).

### SUMMARY

According to a non-limiting embodiment of the present invention, a method for forming a semiconductor device comprises forming a first nanosheet structure in a designated NFET region of a semiconductor substrate and forming a second nanosheet structure in a designated PFET region of the semiconductor substrate. The designated PFET region is separated from the designated NFET region by a distance defining a NFET-to-PFET region (N-to-P region). The method further includes forming, in the N-to-P region, a dielectric bar that separates the first nanosheet structure from the second nanosheet structure. The method further includes forming a first backside contact in the NFET region and forming a first backside contact extension extending from the first backside contact to a first side of the dielectric bar. The method further includes forming a second backside contact in the PFET region and forming a second backside contact extension extending from the second backside contact to an opposing second side of the dielectric bar. The method further includes forming a first backside power rail against at least the first backside contact extension and forming a second backside power rail against at least the second backside contact extension.

According to another non-limiting embodiment of the present invention; a method for forming a semiconductor device comprises forming a first fin trench in a semiconductor substrate to define a first plurality of nanosheet fins in a designated NFET region of the semiconductor substrate, and forming a second fin trench in the semiconductor substrate to define a second plurality of nanosheet fins in a designated PFET region of the semiconductor substrate. The method further includes forming, in the semiconductor substrate, a deep trench between a first nanosheet fin included in the first plurality of nanosheet fins and a second nanosheet fin included in the second plurality of nanosheet fins to define a NFET-to-PFET region (N-to-P region), and forming in the N-to-P region a dielectric bar that separates the first nanosheet fin from the second nanosheet fin. The method further includes forming a first backside contact in the NFET region and forming a first backside contact extension extending from the first backside contact to a first side of the dielectric bar. The method further includes forming a second backside contact in the PFET region, and forming a second backside contact extension extending from the second backside contact to an opposing second side of the dielectric bar. The method further includes forming at least one backside power element on one or both of the first backside contact extension and the second contact extension.

According to yet another non-limiting embodiment of the present invention, a semiconductor device includes at least one first plurality of nanosheet structures at an NFET region of a semiconductor substrate and at least one second plurality of second nanosheet structures at a PFET region of the semiconductor substrate. A first gate wraps around the at least one first plurality of nanosheet structures and a second gate wraps around the at least one second plurality of nanosheet structures. At least one dielectric bar is between the first nanosheet structures and the second nanosheet structures. The semiconductor device further includes a first backside contact in the NFET region and a second backside contact in the PFET region. The first backside contact includes a first backside contact extension that extends to a first side of the at least one dielectric bar. The second backside contact includes a second backside contact extension that extends to an opposing second side of the at least one dielectric bar. One or more backside power elements are on one or both of the first backside contact extension and the second contact extension.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1A depicts a top-down reference view of a semiconductor wafer after an initial set of fabrication operations have been applied as part of a method of fabricating a final semiconductor device according to one or more embodiments of the invention;

FIG. 1B depicts a cross-sectional view of the semiconductor device taken along the cross-section line X shown in FIG. 1A after the initial set of processing operations according to one or more embodiments of the invention;

FIG. 1C depicts a cross-sectional of the semiconductor device view taken along cross-section line Y in FIG. 1A after the initial set of processing operations according to one or more embodiments of the invention;

FIG. 2A depicts the top-down reference view of the semiconductor wafer after a processing operation according to one or more embodiments of the invention according to one or more embodiments of the invention;

FIG. 2B depicts the cross-sectional view taken along the line X of the semiconductor shown in FIG. 2A after the processing operation according to one or more embodiments of the invention;

FIG. 2C depicts the cross-sectional view taken along the line Y of the semiconductor shown in FIG. 2A after the processing operation according to one or more embodiments of the invention;

FIG. 3A depicts the top-down reference view of the semiconductor wafer after a processing operation according to one or more embodiments of the invention according to one or more embodiments of the invention;

FIG. 3B depicts the cross-sectional view taken along the line X of the semiconductor shown in FIG. 3A after the processing operation according to one or more embodiments of the invention;

FIG. 3C depicts the cross-sectional view taken along the line Y of the semiconductor shown in FIG. 3A after the processing operation according to one or more embodiments of the invention;

FIG. 4A depicts the top-down reference view of the semiconductor wafer after a processing operation according to one or more embodiments of the invention according to one or more embodiments of the invention;

FIG. 4B depicts the cross-sectional view taken along the line X of the semiconductor shown in FIG. 4A after the processing operation according to one or more embodiments of the invention;

FIG. 4C depicts the cross-sectional view taken along the line Y of the semiconductor shown in FIG. 4A after the processing operation according to one or more embodiments of the invention;

FIG. 5A depicts the top-down reference view of the semiconductor wafer after a processing operation according to one or more embodiments of the invention according to one or more embodiments of the invention;

FIG. 5B depicts the cross-sectional view taken along the line X of the semiconductor shown in FIG. 5A after the processing operation according to one or more embodiments of the invention;

FIG. 5C depicts the cross-sectional view taken along the line Y of the semiconductor shown in FIG. 5A after the processing operation according to one or more embodiments of the invention;

FIG. 6A depicts the cross-sectional view taken along the line X of the semiconductor shown in FIG. 5A after the processing operation according to one or more embodiments of the invention;

FIG. 6B depicts the cross-sectional view taken along the line Y of the semiconductor shown in FIG. 5A after the processing operation according to one or more embodiments of the invention;

FIG. 7A depicts the cross-sectional view taken along the line X of the semiconductor shown in FIG. 5A after the processing operation according to one or more embodiments of the invention;

FIG. 7B depicts the cross-sectional view taken along the line Y of the semiconductor shown in FIG. 5A after the processing operation according to one or more embodiments of the invention;

FIG. 8A depicts the cross-sectional view taken along the line X of the semiconductor shown in FIG. 5A after the processing operation according to one or more embodiments of the invention;

FIG. 8B depicts the cross-sectional view taken along the line Y of the semiconductor shown in FIG. 5A after the processing operation according to one or more embodiments of the invention;

FIG. 9A depicts the cross-sectional view taken along the line X of the semiconductor shown in FIG. 5A after the processing operation according to one or more embodiments of the invention;

FIG. 9B depicts the cross-sectional view taken along the line Y of the semiconductor shown in FIG. 5A after the processing operation according to one or more embodiments of the invention;

FIG. 10A depicts the top-down reference view of the semiconductor wafer after a processing operation according to one or more embodiments of the invention according to one or more embodiments of the invention;

FIG. 10B depicts the cross-sectional view taken along the line X of the semiconductor shown in FIG. 10A after the processing operation according to one or more embodiments of the invention;

FIG. 10C depicts the cross-sectional view taken along the line Y of the semiconductor shown in FIG. 10A after the processing operation according to one or more embodiments of the invention;

FIG. 11A depicts the cross-sectional view taken along the line X of the semiconductor shown in FIG. 10A after the processing operation according to one or more embodiments of the invention; and

FIG. 11B depicts the cross-sectional view taken along the line Y of the semiconductor shown in FIG. 10A after the processing operation according to one or more embodiments of the invention.

The diagrams depicted herein are illustrative. There can be many variations to the diagram or the operations described therein without departing from the spirit of the invention. For instance, the actions can be performed in a differing order or actions can be added, deleted or modified.

In the accompanying figures and following detailed description of the described embodiments of the invention, the various elements illustrated in the figures are provided with two or three-digit reference numbers. With minor exceptions, the leftmost digit(s) of each reference number correspond to the figure in which its element is first illustrated.

### DETAILED DESCRIPTION

It is understood in advance that although example embodiments of the invention are described in connection with a particular transistor architecture, embodiments of the invention are not limited to the particular transistor architectures or materials described in this specification. Rather, embodiments of the present invention are capable of being implemented in conjunction with any other type of transistor architecture or materials now known or later developed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the present invention, ICs are fabricated in a series of stages, including a front-end-of-line (FEOL) stage, a middle-of-line (MOL) stage, and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts (e.g., CA) and other structures that communicatively couple to active regions (e.g., gate, source, and drain) of the device element. For example, the silicidation of source/drain regions, as well as the deposition of metal contacts, can occur during the MOL stage to connect the elements patterned during the FEOL stage. Layers of interconnections (e.g., metallization layers) are formed above these logical and functional layers during the BEOL stage to complete the IC. Most ICs need more than one layer of wires to form all the necessary connections, and as many as 5-12 layers are added in the BEOL process. The various BEOL layers are interconnected by vias that couple from one layer to another. Insulating dielectric materials are used throughout the layers of an IC to perform a variety of functions, including stabilizing the IC structure and providing electrical isolation of the IC elements. For example, the metal interconnecting wires in the BEOL region of the IC are isolated by dielectric layers to prevent the wires from creating a short circuit with other metal layers.

Backside power delivery is a chip architecture that involves repositioning layers of the BSPDN from the top of the BEOL to the opposite side of the chip to free space on the front side for additional elements (e.g., more signal wires). In other words, a backside-style architecture the BSPDN places layers on the backside of the semiconductor substrate onto which the active devices have been built.

Backside-style architectures require a connection between one or more backside power rails (BSPRs) and a corresponding backside contact to provide electrical continuity to various structures (e.g., gate, source, drain) of the device. However, forming the BSPRs and backside contacts to achieve proper alignment and connection can be difficult due to poor margins and access. For example, current fabrication processes leave very little space between the inner ledges of neighboring BSPRs (e.g., a first BSPR to provide power to a PFET and a second BSPR to provide power to an NFET) at which the connections with the corresponding backside contacts typically occur. As a result, a slight misalignment of a BSPR with its corresponding backside contact can significantly reduce the backside contact-to-BSPR contact area and create a poor connection that undesirably increases the backside contact-to-BSPR contact resistance.

Turning now to an overview of aspects of the present invention, one or more embodiments of the invention address the above-described shortcomings by providing new fabrication methods and resulting structures for providing a semiconductor device having an improved backside power rail to backside contact connection. In one or more non-limiting embodiments of the present invention, the improved backside power rail to backside contact connection is achieved by forming one or more backside contacts that include a backside contact extension which extends laterally over the inner ledge of its corresponding BSPR. In this manner, the a majority of the BSPR, if not the entire BSPR, can still establish electrical contact with its corresponding backside contact even if the BSPR is misaligned from its intended alignment.

In one or more non-limiting embodiments, the improved backside power rail backside contact connection utilizes a dielectric bar that is formed at a region (e.g., the N-to-P region) separating a first backside contact (e.g., a first backside contact corresponding to an NFET) and a neighboring second backside contact (e.g., second backside contact corresponding to a PFET). Accordingly, the dielectric bar can isolate the first backside contact from the neighboring second backside contact, while allowing the backside contacts to be formed with a larger contact area that ensures contact with the majority of their corresponding BSPRs, if not the entire BSPR.

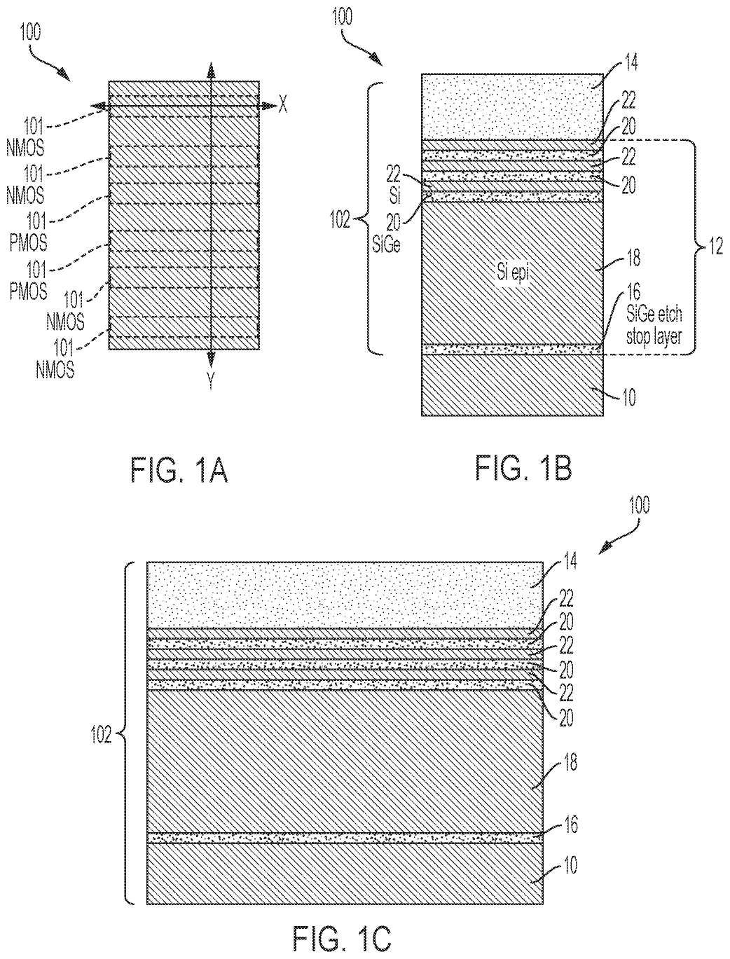

A more detailed description of the fabrication operations and resulting structures according to aspects of the present invention will now be discussed with reference to the drawings. FIG. 1A depicts a top-down reference view of a semiconductor wafer 100 after an initial set of fabrication operations have been applied as part of a method of fabricating a final semiconductor device according to one or more embodiments of the invention. It should be appreciated that top-down reference views described herein assist in providing a reference for the corresponding cross-sectional views of the semiconductor wafer/device 100. For clarity purposes, the top-down reference views may not depict every element shown in their corresponding cross-sectional views.

The top-down reference view in FIG. 1A indicates channel regions 101 designated to contain an active channel corresponding to one or more NFETs and one or more PFETs of a final semiconductor device 100. FIG. 1B depicts a cross-sectional view of the semiconductor device 100 taken along the cross-section line X (e.g., across one or more designated gate regions) shown in FIG. 1A. FIG. 1C depicts a cross-sectional of the semiconductor device 100 view taken along cross-section line Y (e.g., across one or more designated source/drain regions) in FIG. 1A.

Referring to FIGS. 1A through 1C, various FEOL structures 102 (see FIGS. 1A and 1B) are built to form the semiconductor device 100 in an intermediate stage of fabrication prior to completing fabrication of the semiconductor device. The FEOL structures 102 include a substrate 10, a semiconductor stack 12 formed on top of the substrate 10, and a hardmask 14 formed on top of the semiconductor stack 12. The substrate 10 can be formed from a semiconductor material such as, for example silicon (Si). The semiconductor stack 12 includes a first sacrificial layer 16 deposited on an upper surface of a substrate 10. The first sacrificial layer 16 can be, for example, a sacrificial low-Ge % SiGe such as, for example, SiGe30%. The first sacrificial layer 16 serves as an etch stop when removing the substrate 10 in subsequent fabrication operations. In some non-limiting embodiments of the present invention, the first sacrificial layer 16 can be a buried layer of SiO2 when employing a silicon on insulator (SOI) substrate.

The semiconductor stack 12 further includes a semiconductor layer 18 (e.g., a Si epitaxy layer), and alternating layers of a second sacrificial material 20 and an active semiconductor material 22. The semiconductor layer 18 is formed on an upper surface of the first sacrificial layer 16. The alternating layers of the second sacrificial material 20 and the active semiconductor material 22 are stacked on top of the semiconductor layer 18. The layers of second sacrificial material 20 (also referred to herein as the sacrificial layers 20) can formed from a sacrificial material such as, for example, SiGe. The layers of the active semiconductor material 22 (also referred herein as the active semiconductor layers 22) can be silicon (Si) and can serve as the nanosheet layers that make up the semiconductor channel for the semiconductor device 100. The hardmask 14 is formed on top of the upper-most active semiconductor layer 22. The hardmask 14 can be formed from a nitride material such as silicon nitride (SiN), for example, and can be used to facilitate patterning of the semiconductor device 100 as described in greater detail below.

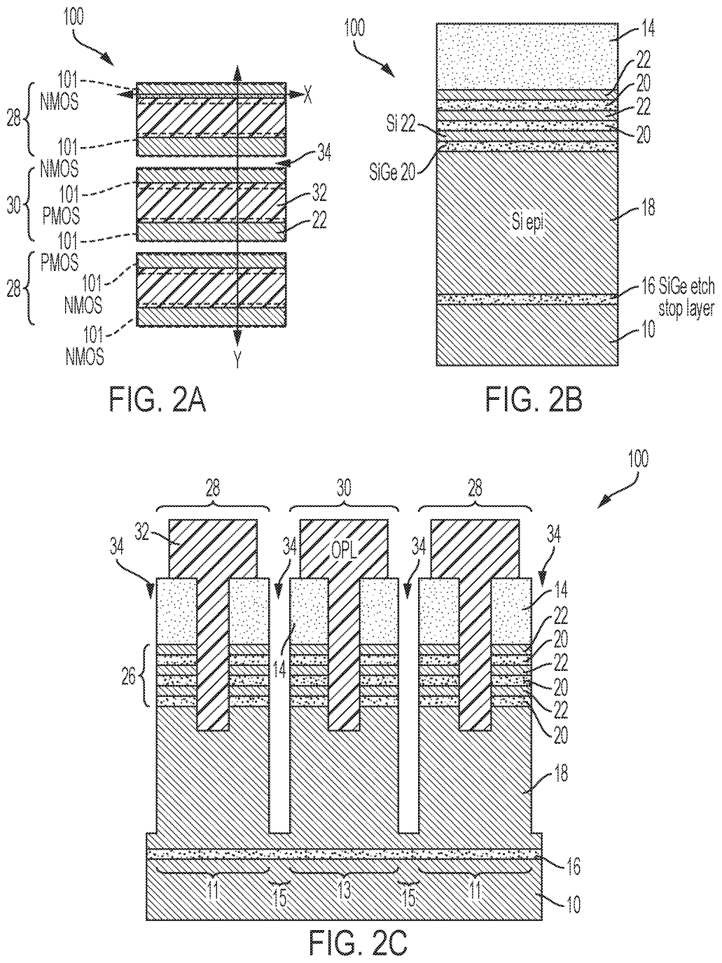

Turning now to FIGS. 2A through 2C, the semiconductor device 100 is illustrated after performing various patterning operations. The pattering operations can include, for example, performing an ultraviolet (UV) or extreme UV (EUV) lithography process to pattern the hardmask 14 and expose portions of the underlying layers of alternating second sacrificial material 20 and active semiconductor material 22. A reactive ion etch (RIE) can then be performed to remove the exposed layers of alternating second sacrificial material 20 and active semiconductor material 22, which form trenches extending into the semiconductor stack 12 and the semiconductor layer 18. Accordingly, the remaining portion of the layers of alternating second sacrificial material 20 and active semiconductor material 22 preserved by hardmask 14 define nanosheet structures 26 (sometimes referred to as nanosheet fins 26) as shown in FIG. 2C.

According to a non-limiting embodiment of the present invention, one or more nanosheet fins 26 are formed in one or more designated NFET regions 11 of the substrate 10 and one or more nanosheet fins 26 are formed in PFET regions 13 of the substrate. The region separating an NFET region 11 from a PFET region 13 is referred to herein as an “NFET-to-PFET” (N-to-P region) 15.

The nanosheet fins 26 include one or more pairs of nanosheet structures formed in a corresponding NFET region 11 which are designated to serve as NFET fins 28 for an NFET, and one or more pairs of nanosheet structures formed in a corresponding PFET region 13 which are designated to serve as PFET fins 30 for a PFET. Fin trenches formed between each pair of NFET fins 28 and each pair of PFET fins 30 are filled with an organic planarization layer (OPL) material 32. Deep trenches 34 extend through the sacrificial layers 20, the active semiconductor layers 22, and the semiconductor layer 18 and separate a designated NFET fin from a neighboring PFET fin to define a width of the NFET-to-PFET region 15. The fin trench (i.e., containing the OPL material 32) between each pair of NFET fins 28 and each pair of PFET fins 30 has a width (e.g., extending in the line X direction) ranging, for example, from about 20 nm to about 100 nm. The deep trenches separating each designated N-to-P region 15 have a width (e.g., extending in the line X direction) that is less than the width of the fin trenches. For example, the width of the deep trenches can range, for example, from about 6 nm to about 50 nm.

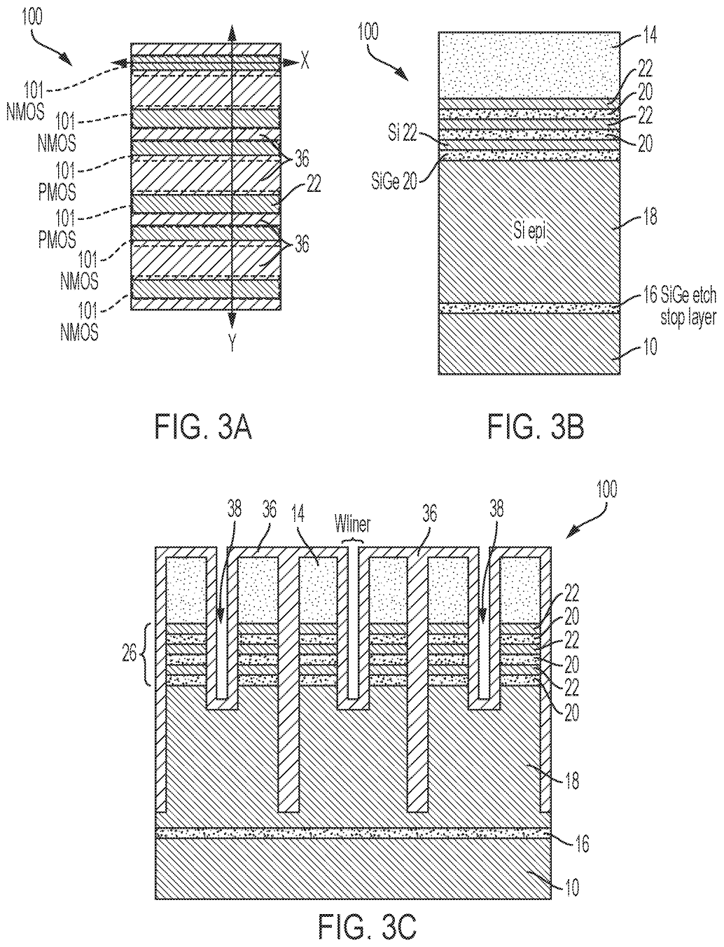

Turning to FIGS. 3A through 3C, the semiconductor device 100 is illustrated after removing the OPL material 32 and depositing a dielectric liner 36. The dielectric liner 36 is formed from various insulative material including, but is not limited to, silicon nitride (SiN). A conformal deposition process such as atomic layer deposition (ALD), for example, is used so that the dielectric liner 36 that conforms to (i.e., lines) the outer surfaces (e.g., the sidewalls and upper surface) of the fin trenches 38 and the deep trenches defining the N-to-P regions 15. The dielectric liner 36 has a thickness ranging, for example, from about 3 nm to about 12 nm.

As shown in FIG. 3C, the fin trench width results in conformal deposition of the dielectric liner 36 without completely filling the fin trench 38. Thus, a space (Wₗᵢₙₑᵣ) is defined between a portion of the dielectric liner 36 formed on a sidewall of a first fin 26 and a sidewall of a neighboring second fin 26. The smaller deep trench width, however, causes the dielectric liner 36 to “pinch off” and completely fill the deep trench 34. As a result, there is no space between portions of the dielectric liner 36 formed in the N-to-P region 15.

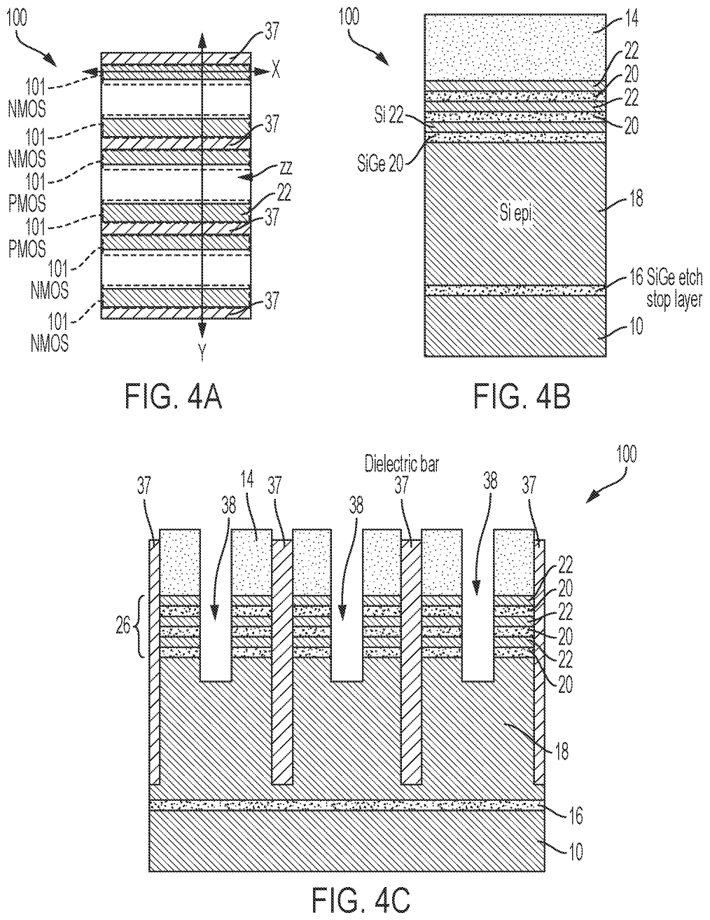

Referring to FIGS. 4A through 4C, the semiconductor device 100 is illustrated after removing portions of the dielectric liner 36 from within the fin trenches 38 and from the top of the hardmasks 14. In one or more non-limiting embodiments of the present invention, an isotropic etch is applied that removes portions of the dielectric liner 36 from the top of the hardmask 14 and the sidewalls of the fin trenches 38.

With continued reference to FIGS. 4B and 4C, portions of the dielectric liner 36 are maintained in the N-to-P region 15 due to the “pinch-off” and omission of the space (Wliner) formed in the fin trenches 38. That is, the isotropic etch is unable to substantially etch the dielectric liner 36 formed in the N-to-P regions 15 since the pinch-off prevents formation of the space (Wliner). Accordingly, the dielectric liner 36 can be removed from within the fin trenches 38 and maintained in the N-to-P regions 15 without requiring an additional mask to preserve the remaining portion of the dielectric liner 36 in the N-to-P regions 15. The portions of the dielectric liner material that are maintained in the N-to-P regions 15 define individual dielectric bars 37. As described herein, the dielectric bars 37 will serve to separate a backside contact (e.g., a backside contact corresponding to an NFET) from a neighboring backside contact (e.g., a backside contact corresponding to a PFET).

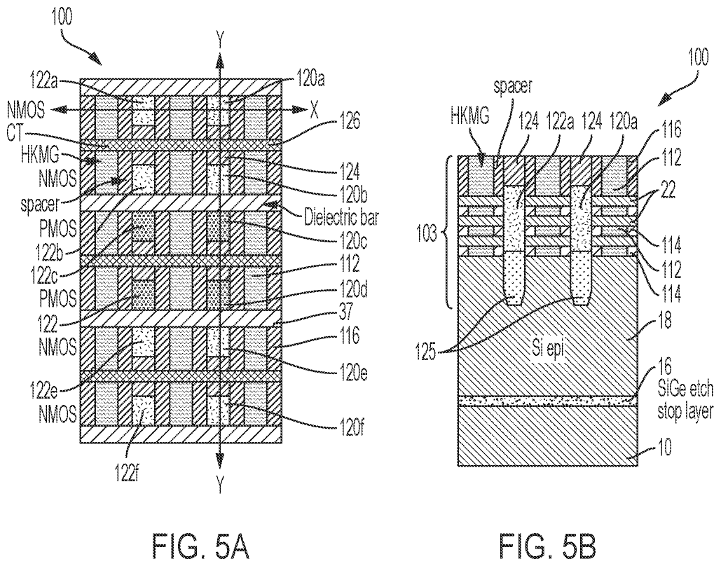

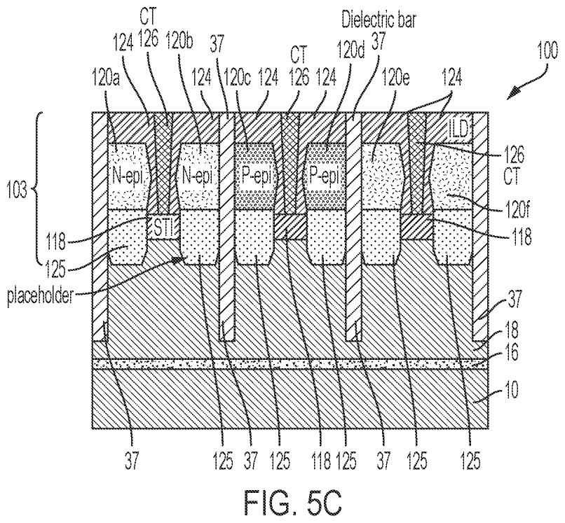

Turning to FIGS. 5A through 5C, the semiconductor device 100 is illustrated following formation of additional FEOL structures 103. The specific examples of the FEOL structures 102 are provided for ease of discussion only and are not meant to be particularly limited. For example, the additional FEOL structures 103 illustrate a nanosheet-style transistor architecture. It should be understood, however, that the nanosheet-style transistor architecture of the FEOL structures 103 is provided for ease of discussion only and that other transistor architectures (e.g., vertical tunneling transistors, planar transistors, finFETs, etc.) are included in the contemplated scope of this disclosure. Similarly, other FEOL structures can be fabricated depending on the needs of a given application, and all such configurations are within the contemplated scope of this disclosure.

The additional FEOL structures 103 include, but are not limited to, replacement metal gates 112, inner spacers 114, gate spacers 116, shallow trench isolation (STI) regions 118, first source/drains 120a-120f, second source/drains 122a-122f, interlayer dielectrics 124, sacrificial contact placeholders 125, and gate cut isolation regions 126. The active semiconductor layers 22 are released and utilized as channel regions after removing the second sacrificial layers 20. Accordingly, the replacement metal gates 112 are formed over corresponding channel regions defined by the active semiconductor layers 22. As used herein, a “channel region” refers to the portion of the active semiconductor layers 22 over which the gate 112 is formed, and through which current passes from source to drain in the final device.

The first source/drains 120a-120f and the second source/drains source/drains 122a-122f can be epitaxially grown from the upper surface of the sacrificial placeholders contact placeholders 125. When performing the epitaxial growth process, a pair of first and second source/drains can be doped with either n-type dopants such as phosphorous or arsenic, for example, to form a corresponding n-type semiconductor device (e.g. NFET or NMOS) or p-type dopants such as boron or gallium, for example, to form a corresponding p-type semiconductor device (e.g. FET or PMOS) or PFET. Referring to FIG. 5C, for example, a first pair of source/drains 120c and 120d can be doped with p-type dopants (e.g., boron or gallium), while a second pair of source/drains 120a and 120b and a third pair of source/drains 120e and 120f can be doped with n-type dopants (e.g., phosphorus or arsenic). Accordingly, the first pair of source/drains 120c and 120d can be used to implement a p-type semiconductor device (e.g. PFET or PMOS), while the second pair of source/drains 120a and 120b and a third pair of source/drains 120e and 120f can be used to implement an n-type semiconductor device (e.g. NFET or NMOS).

With continued reference to FIG. 5C, a first gate cut isolation regions 126 isolates (i.e., electrically insulates) the first pair of source/drains 120c and 120d from one another, a second gate cut isolation region 126 isolates the second pair of source/drains 120a and 120b from one another, and a third gate cut isolation region 126 isolates the third pair of source/drains 120e and 120f from one another. A first dielectric bar 37 isolates the N-to-P region between n-type source/drain 120b and p-type source/drain 120c. Likewise, a second dielectric bar 37 isolates the N-to-P region between p-type source/drain 120d and n-type source/drain 120e.

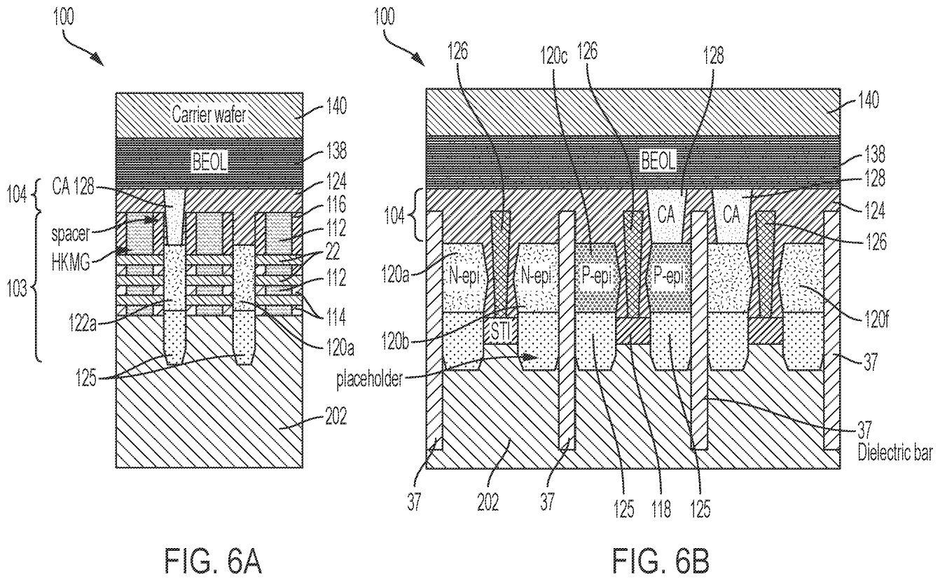

Turning now to FIGS. 6A through 6C, the semiconductor device 100 is illustrated following formation of various middle-of-line (MOL) structures 104 and one or more back-end-of-line (BEOL) structures 138. The specific examples of the MOL structures 104 and BEOL structures 138 are provided for ease of discussion only and are not meant to be particularly limited. It should be appreciated that other MOL and BEOL structures can be fabricated depending on the needs of a given application, and all such configurations are within the contemplated scope of this disclosure.

The various MOL structures 104 include, but are not limited to source/drain contacts (e.g., including contact vias) 128 and one or more additional ILDs 124. The source/drain contacts 128 can serve as front-side contacts that establish an electrically conductive path between the BEOL structures 138 and a corresponding source/drain (e.g., source/drain 122a).

The BEOL structures 138 are formed over the MOL structures 104. The BEOL structures 138 are not meant to be particularly limited and can include, for example, various vias (e.g., “V0”, “V1”), metal layers (e.g., “M1”, “M2”), and any number of intermediate interconnects (metal levels/vias between Mx and Mx+1). In one or more embodiments of the present invention, a carrier wafer 140 is formed over the BEOL structures 138. The carrier wafer 140 can be made from various substrate materials such as, for example, silicon (Si).

With continued reference to FIGS. 6A through 6C, the semiconductor device 100 is illustrated after replacing the substrate 10, the first sacrificial layer 16, and the semiconductor layer 18 with a backside ILD 202. The backside ILD 202 is formed below the replacement metals gates 112 and encapsulates the sacrificial contact placeholders 125 along with the dielectric bars 37.

In one or more embodiments of the present invention, the backside ILD 202 is formed using a wafer flip process whereby the semiconductor wafer 100 is flipped and the substrate 10, first sacrificial layer 16, and semiconductor layer 18 are removed using one or more known etching and/or planarization techniques. For example, the substrate 110 can be removed using any suitable technique, such as grinding and/or chemical-mechanical planarization (CMP) to the sacrificial layer 16 (i.e., stopping on the etch stop). The etch stop layer 16 can then be removed using a dry etch technique that applies a chemical etchant that attacks the material of the sacrificial layer 16. After removing the sacrificial layer 16, the semiconductor layer 18 can be removed using a wet etch technique that applies a chemical etchant the selectively etches the material of the semiconductor layer 18 without attacking the material of the sacrificial contact placeholders 125.

Following removal of the substrate 10, the first sacrificial layer 16 and the semiconductor layer 18, the backside ILD 202 can be deposited using, for example, chemical vapor deposition (CVD). Accordingly, the backside ILD 202 covers the backside of the replacement gates 112, and encapsulates the sacrificial contact placeholders 125 along with the dielectric bars 37.

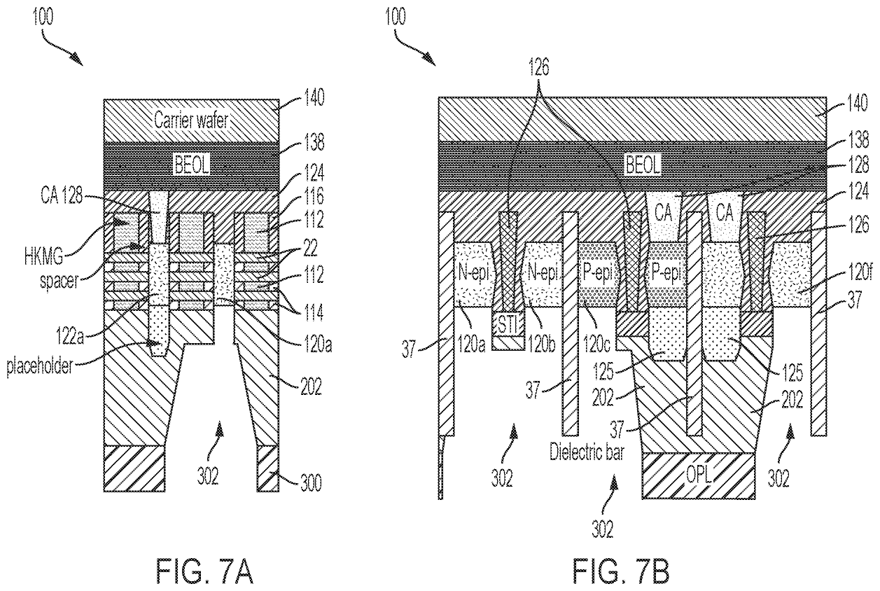

With reference now to FIGS. 7A and 7B, the semiconductor device 100 is illustrated after forming one or more backside source/drain contact trenches 302. The backside source/drain contact patterns 302 can be formed using any suitable technique, such as, for example, using a wet etch, a dry etch, or a combination of sequential wet and/or dry etches. In one or more non-limiting embodiments of the present invention, a first etching process (e.g., using a first type of chemical etchant) selective to the material of the dielectric bar 37 can be performed to remove the portions of the backside ILD 202 that are not covered by the patterned OPL 300 and expose the bottom surface of one or more targeted sacrificial contact placeholder 125. A second etching process (e.g., using a second different type of chemical etchant) selective to the source/drain material can then be performed to remove the exposed sacrificial contact placeholder 125.

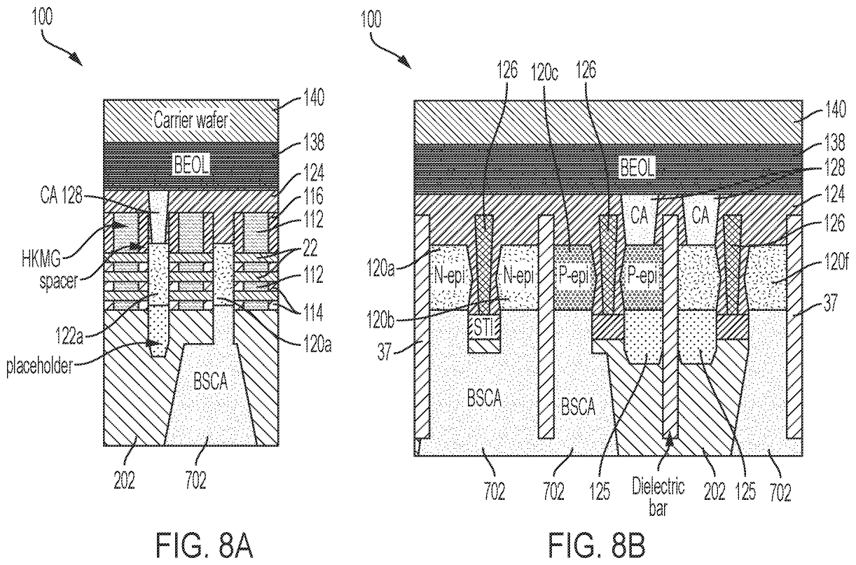

Turning to FIGS. 8A and 8B, the semiconductor device 100 is illustrated after forming one or more backside source/drain contacts 702. The backside source/drain contacts 702 can be formed by depositing a suitable contact metallization material, such as, for example, metal, a conductive non-metal, or combinations thereof, in the backside source/drain contact trenches 302, and then performing a CMP process that stops on the backside ILD 202. Accordingly, the remaining metallization material defines the backside source/drain contacts 702. In one or more non-limiting embodiments, a portion of one or more backside source/drain contacts 702 (e.g., backside source/drain contact 702 corresponding to p-type source/drain 120c) extends below the gate cut isolation region 126.

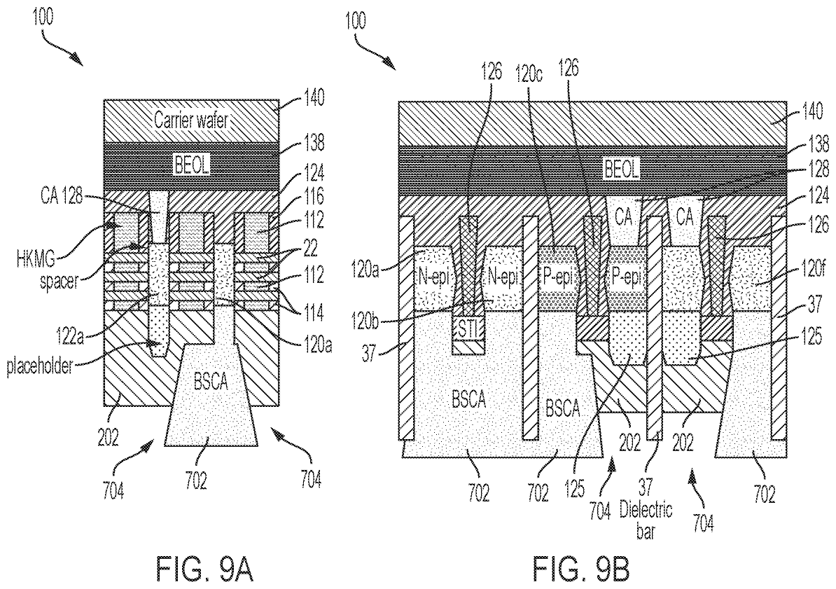

Referring to FIGS. 9A and 9B, the semiconductor device 100 is illustrated after removing a portion of the backside ILD 202 to form one or more contact extension trenches 704. The contact extension trenches 704 can be formed in the region (e.g., the N-to-N region) containing a pair of n-type source/drains (e.g., 120e and 120f) and/or a region (e.g., the P-to-P region) containing a pair of p-type source/drains (e.g., source/drains 120c and 120d). In one or more non-limiting embodiments, a wet etching process that applies a chemical etchant selective to the oxide material of the backside ILD 202 can be used to recess the backside ILD 202 without substantially attacking the surrounding dielectric bar 37 and backside source/drain contacts 702. As further shown in FIG. 9B, one or more of the contact extension trenches 704 can expose a bottom portion of the dielectric bar 37 located in the N-to-P region 37 separating n-type source/drain 120e from p-type source/drain 120d.

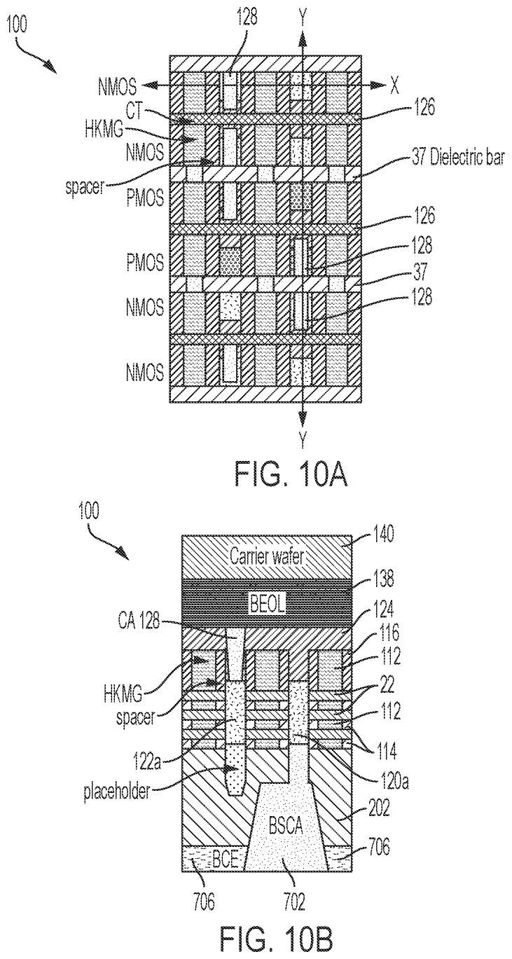

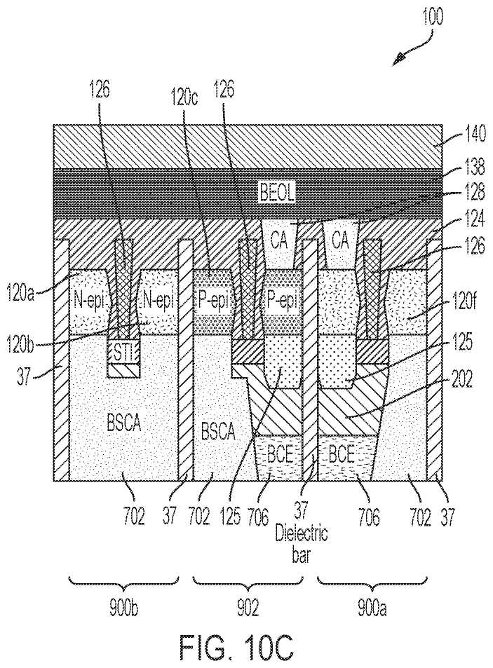

With reference now to FIGS. 10A, 10B and 10C, the semiconductor device 100 is illustrated following the formation of one or more backside contact extensions 706. The backside source/drain extensions 706 can be formed by depositing a suitable contact metallization material, such as metal, a conductive non-metal, or combinations thereof, for example, in the contact extension trenches 704 and then performing a CMP process that stops on the dielectric bars. Accordingly, the remaining metallization material defines backside contact extensions 706.

In some embodiments of the present invention, the contact metallization material used to form the backside contact extensions 706 is the same contact metallization material used to form the backside source/drain contacts 702. In other embodiments of the present invention, the contact metallization material used to form the backside contact extensions 706 is different than the contact metallization material used to form the backside source/drain contacts 702.

In one or more non-limiting embodiments, a first backside contact extension 706 corresponds to a first backside contact 702 formed in the designated NFET region and is configured to contact a first source/drain (e.g., source/drain 120f) formed in the designated NFET region. The first backside contact extension 706 extends from the first backside contact 702 and contacts a first side of the dielectric bar 37 while overlapping the sacrificial contact placeholder 125. Likewise, a second backside contact extension 706 corresponds to a second backside contact 702 formed in the designated PFET region and is configured to contact a second source/drain (e.g., source/drain 120c) formed in the designated PFET region. The second backside contact extension 706 extends from the second backside contact 702 and contacts an opposing second side of the dielectric bar 37 while overlapping the sacrificial contact placeholder 125. Accordingly, the dielectric bar 37 separates and isolates (e.g., electrically insulates) the first backside contact extension 706 formed in the designated NFET region from the second backside contact extension 706 formed in the designated PFET region. As shown in FIGS. 10A through 10C, the dielectric bars 37 also separate the channels (i.e., active semiconductor layer 22), gates 112, and source/drains 120 located in the NFET region from neighboring channels 22, gates 112, and source/drains 120 located in the PFET region.

As further shown in FIGS. 10A through 10C, one or more non-limiting embodiments of the present invention provides a semiconductor device 100 that includes a first NFET 900a formed at a first NFET region, a second NFET 900b formed at a second NFET region, a PFET 902 formed at a PFET region located between the first NFET 900a and the second NFET 900b, and a plurality of dielectric bars 37. The plurality of dielectric bars 37 includes a first dielectric bar 37 between the first NFET 900a and the PFET 902, and a second dielectric bar 37 between the second NFET 900b and the PFET 902. The first and second dielectric bars 37 separate and isolate (e.g., electrically insulate) the PFET 902 from the first and second NFETs 900a and 900b. The backside source/drain contact 702 corresponding to the PFET 902 is also confined between the first and second dielectric bars 37. Additional third and fourth dielectric bars 37 are formed on opposing sides of the first and second NFETs 900a and 900b, respectively. Accordingly, the backside source/drain contact 702 and the backside contact extension 706 corresponding to the first NFET 900a is confined between the first dielectric bar 37 contacting the PFET 902 and the third dielectric bar 37 contacting the side of the first NFET 900a. Likewise, the backside source/drain contact 702 and the backside contact extension 706 corresponding to the second NFET 900b is confined between the first dielectric bar 37 contacting the PFET 902 and the fourth dielectric bar 37 contacting the side of the second NFET 900b.

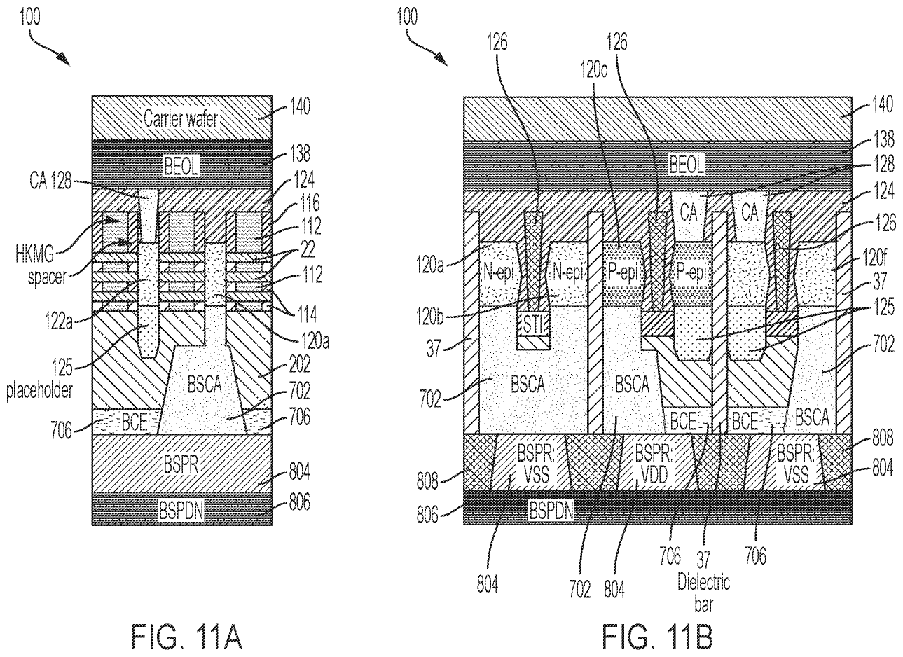

Turning to FIGS. 11A and 11B, the semiconductor device 100 is illustrated following the formation of one or more backside power elements. According to a non-limiting embodiment, the backside power elements include, but are not limited to, one or more backside power rails (BSPRs) 804 and a backside power delivery network 806 (BSPDN). In one or more non-limited embodiments, the BSPRs 804 and the BSPDN 806 can be formed over the semiconductor wafer 100 with respect to a post-flip orientation, which has been omitted for clarity.

One or more of the BSPRs 804 can serve as a VDD BSPR 804 that is connected to the power supply (VDD), or as a VSS BSPR 804 that is connected to ground (VSS). Thus, the BSPRs 804 can serve as electrically conductive terminals which connect the backside source/drain contacts 702 to the BSPDN 806.

The BSPDN 806 can include any number of conductive/metal layers, lines, and vias, and can be formed in a similar manner as the BEOL structures discussed previously, except that the BSPDN 806 is formed on an opposite side of the semiconductor wafer 100. In some embodiments, an additional backside dielectric 808 is formed prior to the BSPR 804 and the BSPDN 806 as shown in FIG. 11B. The additional backside dielectric 808 can be formed of similar materials and in a similar manner as the backside dielectric 202.

As described herein, one or more backside contact extensions 706 can be formed to extend laterally over the inner ledge of its corresponding BSPR 804. In this manner, the a majority of the BSPR 804, if not the entire BSPR 804, can still establish electrical contact with its corresponding backside source/drain contact 702 even when the BSPR 804 is misaligned from its intended alignment. When, for example, a BSPR 804 is misaligned with respect to the backside source/drain contact 702 (e.g., BSPR VDD is offset further to the left than intended), the entire upper surface of the BSPR 804 still establishes full electrical connection due to its contact with the backside contact extensions 706 and the backside source/drain contact 702. In this manner, an improved backside power rail to backside contact connection is achieved which increases the backside contact-to-BSPR contact area available to the backside source/drain contact 702, and which reduces the possibility of undesirable increased backside contact-to-BSPR contact resistance if the backside source/drain contact 702 is misaligned during the BEOL process.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Similarly, the term “coupled” and variations thereof describes having a communications path between two elements and does not imply a direct connection between the elements with no intervening elements/connections between them. All of these variations are considered a part of the specification. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, are used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (e.g., rotated 90 degrees or at other orientations), and the spatially relative descriptors used herein should be interpreted accordingly.

The terms “about,” “substantially,” “approximately,” and variations thereof, are intended to include the degree of error associated with measurement of the particular quantity based upon the equipment available at the time of filing the application. For example, “about” can include a range of +8% or 5%, or 2% of a given value.

The phrase “selective to,” such as, for example, “a first element selective to a second element,” means that the first element can be etched and the second element can act as an etch stop (i.e., the second element remains).

The term “conformal” (e.g., a conformal layer or a conformal deposition) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a <100> orientated crystalline surface can take on a <100> orientation. In some embodiments of the invention of the invention, epitaxial growth and/or deposition processes can be selective to forming on semiconductor surface, and may or may not deposit material on other exposed surfaces, such as silicon dioxide or silicon nitride surfaces.

As used herein, “p-type” refers to the addition of impurities to an intrinsic semiconductor that creates deficiencies of valence electrons. In a silicon-containing substrate, examples of p-type dopants, i.e., impurities, include but are not limited to, boron, aluminum, gallium, and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method for forming a semiconductor device, the method comprising:
forming a first nanosheet structure in a designated NFET region of a semiconductor substrate and a second nanosheet structure in a designated PFET region of the semiconductor substrate, the designated PFET region separated from the designated NFET region by a distance defining a NFET-to-PFET region (N-to-P region);
forming, in the N-to-P region, a dielectric bar that separates the first nanosheet structure from the second nanosheet structure;
forming a first backside contact in the NFET region and forming a first backside contact extension extending from the first backside contact to a first side of the dielectric bar;
forming a second backside contact in the PFET region and forming a second backside contact extension extending from the second backside contact to an opposing second side of the dielectric bar; and
forming a first backside power rail against at least the first backside contact extension and forming a second backside power rail against at least the second backside contact extension.

2. The method of claim 1, wherein the dielectric bar is disposed between the first backside power rail and the second backside power rail.

3. The method of claim 2, wherein forming the dielectric bar comprises:
forming, in the semiconductor substrate, a deep trench defines the N-to-P region separating the first nanosheet structure from the second nanosheet structure;
depositing a dielectric liner that conforms to sidewalls and an upper surface of the first and second nanosheet structures, and conforms to sidewalls and a base of the deep trench; and
removing a first portion of the dielectric liner that conforms to the sidewalls and the upper surface of the first and second nanosheet structures, while maintaining a second portion of the dielectric liner in the deep trench so as to form the dielectric bar.

4. The method of claim 3, wherein forming the first backside contact and the first backside contact extension, and the second backside contact and the second backside contact extension comprises:
depositing an interlayer dielectric (ILD) on the semiconductor substrate to encapsulate the dielectric bar;
replacing a first portion of the ILD with a first metal material that defines the first and second backside contacts; and
replacing a second portion of the ILD with a second metal material that defines the first and second backside contact extensions.

5. The method of claim 4, wherein the dielectric bar comprises a first dielectric material and the ILD comprises a second dielectric material different form the first dielectric material.

6. The method of claim 5, wherein forming the first backside contact and the first backside contact extension, and the second backside contact and the second backside contact extension further comprises:
performing a first etching process selective to the second dielectric material so as to form contact trenches;
filling the contact trenches with the first metal material;
performing a second etching process selective to the second dielectric material so as to form contact extension trenches without etching the dielectric bar; and
filling the contact extension trenches with the second metal material.

7. The method of claim 1, further comprising forming a backside power distribution network (BSPDN) against one or both of the first backside power rail and the second backside power rail.

8. A method for forming a semiconductor device, the method comprising:
forming a first fin trench in a semiconductor substrate to define a first plurality of nanosheet fins in a designated NFET region of the semiconductor substrate;
forming a second fin trench in the semiconductor substrate to define a second plurality of nanosheet fins in a designated PFET region of the semiconductor substrate;
forming, in the semiconductor substrate, a deep trench between a first nanosheet fin included in the first plurality of nanosheet fins and a second nanosheet fin included in the second plurality of nanosheet fins to define a NFET-to-PFET region (N-to-P region);
forming, in the N-to-P region, a dielectric bar that separates the first nanosheet fin from the second nanosheet fin;
forming a first backside contact in the NFET region and forming a first backside contact extension extending from the first backside contact to a first side of the dielectric bar;
forming a second backside contact in the PFET region and forming a second backside contact extension extending from the second backside contact to an opposing second side of the dielectric bar; and
forming at least one backside power element on one or both of the first backside contact extension and the second contact extension.

9. The method of claim 8, wherein forming the at least one backside power element comprises:
forming a first backside power rail having a first surface against the first backside contact extension;
forming a second backside power rail having a first surface against the second backside contact extension; and
forming a backside power distribution network (BSPDN) against an opposing second surface of the first backside power rail and against an opposing second surface of the second backside power rail.

10. The method of claim 9, wherein the dielectric bar is disposed between the first backside power rail and the second backside power rail.

11. The method of claim 10, further comprising forming a first gate cut isolation region in the first fin trench and a second gate cut isolation region in the second fin trench.

12. The method of claim 11, wherein forming the dielectric bar, the first gate cut isolation region, and the second gate cut isolation region comprises:
depositing a dielectric liner that conforms to sidewalls and an upper surface of the first plurality of nanosheet structures along with sidewalls and a base of the first fin trench, conforms to sidewalls and an upper surface of the second plurality of nanosheet structure along with sidewalls and a base of the second fin trench, and conforms to sidewalls and a base of the deep trench; and
removing a first portion of the dielectric liner from the sidewalls and the upper surface of the first plurality of nanosheet structures and second plurality of nanosheet structures, while maintaining a second portion of the dielectric liner in the first and second fin trenches so as to define the first and second gate cut isolation regions, and in the deep trench so as to form the dielectric bar.

13. The method of claim 12, wherein forming the first backside contact and the first backside contact extension, and the second backside contact and the second backside contact extension comprises:
depositing an interlayer dielectric (ILD) on the semiconductor substrate to encapsulate the dielectric bar;
replacing a first portion of the ILD with a first metal material that defines the first and second backside contacts; and
replacing a second portion of the ILD with a second metal material that defines the first and second backside contact extensions.

14. The method of claim 13, wherein the dielectric bar comprises a first dielectric material and the ILD comprises a second dielectric material different form the first dielectric material.

15. The method of claim 14, wherein forming the first backside contact and the first backside contact extension, and the second backside contact and the second backside contact extension further comprises:
performing a first etching process selective to the second dielectric material so as to form contact trenches;
filling the contact trenches with the first metal material;
performing a second etching process selective to the second dielectric material so as to form contact extension trenches without etching the dielectric bar; and
filling the contact extension trenches with the second metal material.

16. A semiconductor device comprising:
at least one first plurality of nanosheet structures at an NFET region of a semiconductor substrate and at least one second plurality of nanosheet structures at a PFET region of the semiconductor substrate;
a first gate wrapping around the at least one first plurality of nanosheet structures and a second gate wrapping around the at least one second plurality of nanosheet structures;
at least one dielectric bar between the at least one first plurality of nanosheet structures and the at least one second plurality of nanosheet structures;
a first backside contact in the NFET region, the first backside contact including a first backside contact extension extending to a first side of the at least one dielectric bar;
a second backside contact in the PFET region, the second backside contact including a second backside contact extension extending to an opposing second side of the at least one dielectric bar; and
at least one backside power element on one or both of the first backside contact extension and the second contact extension.

17. The semiconductor device of claim 16, wherein the at least one dielectric bar separates the at least one first plurality of nanosheet structures, the first gate, and the first backside contact extension from the at least one second plurality of nanosheet structures, the second gate, and the second backside contact extension.

18. The semiconductor device of claim 17, wherein:
the at least one first plurality of nanosheet structures includes a first plurality of nanosheet structures of a first NFET located at a first NFET region and a second plurality of nanosheet structures of a second NFET located at a second NFET region; and
the at least one second plurality of nanosheet structures includes a plurality of nanosheet structure of a PFET located at a PFET region between the first NFET and the second NFET region.

19. The semiconductor device of claim 18, wherein:
the at least one dielectric bar includes a first dielectric bar between the first NFET region and the PFET region, and a second dielectric bar between the second NFET region and the PFET region; and
the second backside contact and the second backside contact extension are confined by the first and second dielectric bars.

20. The semiconductor device of claim 19, wherein a first gate cut isolation is interposed between a first nanosheet structure and a second nanosheet structure included in the first plurality of nanosheet structures, and a second gate cut isolation region is interposed between a first nanosheet structure and a second nanosheet structure included in the second plurality of nanosheet structures, and
wherein one or both of the first backside contact includes a portion that extends beneath the first gate cut isolation region or beneath the second gate cut isolation region.
